(19) United States
(12) Patent Application Publication
(10) Pub. No.: US 2007/0241344 A1
(43) Pub. Date: Oct. 18, 2007

(54) Semiconductor Light Emitting Device

(76) Inventors: Koichiro Adachi, Musashino (JP); Kouji Nakahara, Kunitachi (JP); Jun-ichi Kasai, Kunitachi (JP); Takeshi Kitatani, Hino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/733,229

(22) Filed: Apr. 10, 2007

(30) Foreign Application Priority Data
Apr. 12, 2006 (JP) 2006-109558

(51) Int. Cl. H01L 33/00

(52) U.S. Cl. 257/79

(57) ABSTRACT

For a semiconductor light emitting device using GaInNAs as an active layer, since GaInNAs includes N, the critical thickness is reduced and it is difficult to lengthen the wavelength of a laser beam. A semiconductor light emitting device is prepared, which has an active layer comprising a quantum well layer formed by successively stacking a GaInNAs layer and a GaInAs layer and GaAs barrier layers stacked on both sides of the quantum well layer. The quantum level of the conduction band is present above the conduction band edge of the GaInAs layer.

### CLAIM OF PRIORITY

The present application claims priority from Japanese application No. 2006-109558, filed on Apr. 12, 2006, the content of which is hereby incorporated by reference into this application.

### BACKGROUND OF THE INVENTION

1. Field of the Invention

The present invention relates to semiconductor light emitting devices and more particularly to a technique effective in application for a semiconductor laser or semiconductor optical amplification device, a semiconductor optical modulation device, or a semiconductor light emitting device integrating them.

2. Description of the Related Arts

With the proliferation of the Internet, usage of information networks have rapidly increased, and the increase of the transmission capacity in optical communication systems is currently required. Increase in communication speed and capacity has become an important task not only for long distance communication in inter-urban trunk line networks but also in medium to short distance communication of metro-network in urban areas. It is expected that a large market for 10 Gbit/s (transmission distance: 300 m) LRM will be developed in the feature. Further, while the market for 40 Gbit/s is still in a small scale according to the current estimate, it is necessary to develop transmission/receiving optical device at a low cost for the increase of traffic in the Internet in the feature. Correspondingly, high speed and inexpensive optical modules used for optical connection between routers provided in or between stations in metro-networks have been demanded. For a semiconductor transmissions receiving optical device as a key device, therefore, a semiconductor laser of 1.3 μm band or 1.55 μm band with less transmission loss in a silica fiber is necessary.

In the emission wavelength range of 1.3 μm band or 1.55 μm band, materials on InP substrates are used generally. However, since conventional long wavelength band lasers have a drawback of poor temperature characteristics and need a cooling device, it is extremely important to develop a long wavelength band laser having good temperature characteristics for reducing the power consumption and reducing the cost. The reason for poor temperature characteristics is mainly attributable to the overflow of carriers because of small band discontinuity of a conduction band.

In recent years, GaInNAs has been noted as a material capable of manufacturing a semiconductor laser emitting in 1.3 μm band on a GaAs substrate.

GaInNAs is a III-V group mixed crystal semiconductor containing N and other group V element, which is a material capable of matching a lattice constant to GaAs by adding N to GaInAs having a larger lattice constant than GaAs. Further, since tensile strain exerts by N addition, a band gap is decreased and light emission in 1.3 and 1.5 μm bands is possible. In Japanese Journal of Applied Physic, Vol. 35(1996) pp. 1273-1275) (Non-Patent Document 1), a band line-up of GaInNAs is calculated by Kondo, et al. Since the band gap is decreased and, at the same time, the band is lowered both for the conduction band and the valence electron band by the addition of N, it is expected that the band discontinuity of the conduction band is increased and the temperature characteristic can be improved remarkably.

With a view point of wavelength lengthening, it is desirable to increase both N and In compositions in GaInNAs. For example, JP-A No. 10-270798 (Patent Document 1) discloses a semiconductor light emitting device using Ga_{0.9}In_{0.1}N_{0.03}As_{0.97} matching to a GaAs substrate and having a PL wavelength of 1.3 μm as an active layer. However, this involves a problem that a threshold current density increases abruptly as the N composition is increased. For example, JP-A No. 2000-200647 (Patent Document 2) discloses the result of an experiment that a threshold current density increases by about five times when y increases from 1.5% to 2.5% in a Ga_{0.9}In_{0.1}N_{y}As_{1-y} laser with 10% In composition. Accordingly, a method of increasing the In composition and decreasing the N composition has been adopted generally, and a GaInNAs type quantum well having a high compression strain of about 2% or more relative to a substrate is used as an active layer. Such a highly strained quantum well suffers from restriction for the device design such that the critical thickness is as thin as several nm making it difficult for wavelength lengthening or the number of quantum wells is restricted. Particularly, while a multi-quantum well (MQW) is necessary for coping with higher speed intended for 10 Gbit/s or 40 Gbit/s, since the critical thickness is reduced as the number of the quantum wells increases generally, compatibility between the increase of speed and the wavelength lengthening is difficult.

Therefore, various strain compensation techniques have been proposed so far. For example, JP-A No. 10-126004 (Patent Document 3) proposes a method of compensating the strain of GaInNAs type quantum well active layer by using a GaInNPAs type material barrier layer having smaller lattice constant than the substrate and not containing Al as a strain compensation layer, and facilitating the boundary control between the active layer and the barrier layer. Further, JP-A No. 10-145003 discloses a method of moderating strain of the active layer while ensuring the confining potential of electrons and holes sufficient for laser emission by using GaNPAs or GaNAs material for the strain compensation layer. Further, JP-A No. 2004-200647 (Patent Document 2) discloses a method of decreasing the N composition of a strain compensation layer to less than that of the GaInNAs type quantum well active layer thereby making the band discontinuity of the conduction band larger to improve the temperature characteristic, as well as improving the crystallinity of a barrier layer as an underlayer to the active layer to grow an active layer at high quality.

Further, the strain compensation technique is generally used also in semiconductor quantum well lasers having active lasers other than GaInNAs type quantum wells. For example, 11th International Conference on Indium Phosphide and Related Materials 1999 MoPO2 discloses a method of introducing an InAsP strain compensation intermediate layer adjacent with both sides of a GaInAsP quantum well.

IEEE, Photonics Technology Letter, Vol. 9, No. 11 (1997) pp 1448-1450 (Non-Patent Document 2) and IEEE, Photonics Technology Letter, Vol. 14, No. 7(2002) pp 896-898 (Non-Patent Document 3) disclose a method of lengthening the wavelength without strain compensation while keeping the GaInNAs quantum well layer to less than a critical thickness. In the examples described above, an GaInNAs type intermediate layer having an In composition different from a GaInNAs quantum well layer and lattice matching to GaAs is stacked between the GaInNAs quantum well layer and GaAs barrier layers stacked on both sides thereof thereby increasing the effective thickness of the quantum well layer and lengthening the wavelength.

However, since it has been known from quantum mechanical calculation using effective mass approximation that the high speed property of a laser lowers remarkably in the structure described above, details are to be described below. FIG. 9 is a typical example of an energy structure of a GaInNAs quantum well disclosed in Non-Patent Document 1 above. The quantum well in FIG. 9 includes a GaInNAs layer 3, GaAs barrier layers 2 and 6 stacked on both sides of the GaInNAs layer 3, and GaInNAs intermediate layers 7 stacked respectively between the GaInNAs layer 3 and the GaAs barrier layer 2 and between the GaInNAs layer 3 and the GaAs barrier layer 6.

Further, the GaInNAs intermediate layer 7 has such an In composition that the band gap energy is larger than that of the GaInNAs layer 3. In the known example, the first quantum level of the conduction band is present below the conduction band edge of the GaInNAs intermediate layer 7. In such a case, it has been known by the quantum mechanical calculation using the effective mass approximation that the carrier density at the first quantum level lowers by about 40 to 50% compared with a case where the first quantum level is present above the conduction band edge of the GaInNAs intermediate layer 7. As the carrier density decreases, a differentiation gain concerning the high speed property also decreases. Accordingly, the high speed property is remarkably lowered.

Further, IEEE, Journal of Quantum Electronics, Vol. 39, No. 8(2003) discloses an example of where an intermediate layer is introduced and the first quantum levels for the conduction band and the valence electron band are present respectively on the higher energy side than the band edge of the intermediate layer. However, in this example, the intermediate layer is applied for improving the property of an electro-absorption optical modulator and it is introduced for compensation of strain.

### SUMMARY OF THE INVENTION

GaInNAs involves a problem that the critical thickness is thin irrespective of the fact that the strain is smaller compared with GaInAs of the same In composition as that of GaInNAs. The problem is to be described below. FIG. 1 shows a relation between the thickness of a quantum well layer and a threshold current density of GaInNAs and GaInAs triple quantum well (TQW) lasers determined experimentally by the inventors of the present application. In view of the FIG. 1, the threshold current density of the GaInNAs laser abruptly increases by about three times when the quantum layer thickness increases from 5 to 7 nm. It is estimated from this that the critical thickness of the GaInNAs-TQW is about 5 nm or less. On the other hand, in the GaInAs laser, even when the well layer thickness increases in the same range, the threshold current density scarcely changes and it is estimated that the critical thickness is 7 nm or more. GaInAs has a compressive strain to GaAs. Accordingly, GaInNAs obtained by adding N that gives tensile strain to GaInAs has a strain less than that of GaInAs. Accordingly, compared with GaInAs, GaInNAs has less strain and thinner critical thickness. Since the In composition of GaInNAs and that of GaInAs are similar in percentage, which is about 31%, it is considered that the difference of the critical thickness between the two materials is attributable to N. Further, since GaInNAs of less strain than GaInAs has a thinner critical thickness, N addition has larger contribution than strain to the lowering of the durability relative to the critical thickness.

In view of the above, the present invention intends to moderate the restriction of a critical thickness attributable to N addition in the GaInNAs quantum well and provide a semiconductor light emitting device having a GaInNAs type quantum well layer of a structure in which the wavelength is lengthened at a low threshold current, which is suitable for optical communication.

The object can be attained in a semiconductor light emitting device having at least one active layer that emits light and that is formed above a semiconductor substrate. The active layer comprises a quantum well layer and semiconductor barrier layers. The quantum well layer is formed by stacking a first semiconductor layer and a second semiconductor layer that is adjacently formed one side or both sides of the first semiconductor layer and that has a larger band gap energy than that of the first semiconductor layer. The semiconductor barrier layers each have a band gap energy larger than that of the quantum well layer and are stacked on both sides of the quantum well layer. The quantum level of the quantum well layer is present on the higher energy side than the band edge of the second semiconductor layer.

Since GaInAs has more preferred critical thickness durability than GaInNAs, a GaInNAs/GaInAs multi-layer quantum well with the net thickness exceeding the critical thickness of GaInNAs can be prepared by stacking the GaInAs layer to the GaInNAs quantum well layer and the wavelength can be lengthened at a low threshold current.

### BRIEF DESCRIPTION OF THE DRAWINGS

FIG. 1 is a graph showing a relation between a quantum well width and a threshold current density in GaInNAs-TQW and GaInAs-TQW;

FIG. 2 is a structural view of a narrow stripe edge emission type laser;

FIG. 3 is a graph showing an energy structure of a quantum well of a semiconductor laser device according to a first embodiment of the invention;

FIG. 4 is a graph showing a relation between a quantum well width and an emission wavelength in the case of fixing the thickness of a GaInNAs layer according to the first embodiment of the invention;

FIG. 5 is a graph showing a relation between L1 and 12 in the case where the first quantum level energy of a conduction band is equal to the energy at the conduction band edge of a GaInAs layer;

FIG. 6 is a graph showing an energy structure of a quantum well layer of a semiconductor laser device according to a second embodiment of the invention;

FIG. 7 is a graph showing a relation between a quantum well width and an emission wavelength in the case of fixing the thickness of a GAInNAs layer according to the second embodiment of the invention;

FIG. 8 is a view showing a surface emitting laser; and

FIG. 9 is a view showing a quantum well structure for lengthening the wavelength by providing an intermediate layer between a quantum well layer and a semiconductor barrier layer of an existent example.

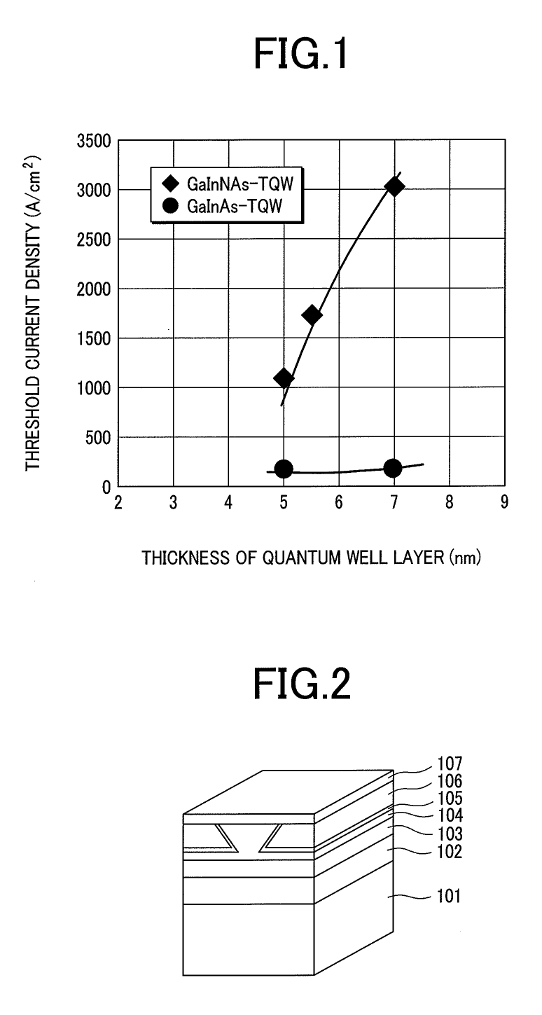

### DETAILED DESCRIPTION OF THE PREFERRED EMBODIMENTS

Preferred embodiments of the invention are to be described with reference to the drawings.

### First Embodiment

A first embodiment is an example of applying the invention to a narrow stripe type edge emitting laser. FIG. 2 shows a device structure of a narrow stripe edge emitting laser. In FIG. 2, reference numeral 101 denotes an n-GaAs substrate; 102, an n-GaInP cladding layer having a carrier concentration of 1×10¹⁸ cm⁻³; 103, an active layer; 104, a p-GaInP cladding layer having a carrier concentration of 1×10¹⁸ cm⁻³; 106, a polyimide insulation layer; 105, an SiO₂ protective film; and 107, a p-electrode layer. A resonator length is 200 μm and coatings having reflectivity of 70% and 90% are applied to the front and back edges of a device, respectively. An epitaxial structure of the laser structure shown in FIG. 2 can be successively grown, for example, by a gas source molecular beam epitaxy using N radicals. Further, a similar structure can be obtained also by metal organic vapor phase epitaxy method. The first embodiment has a feature of having triple quantum well (TQW) structure in which the active layer 103 shown in FIG. 2 is formed by stacking three layers of the active layer shown in FIG. 3.

FIG. 3 is a view showing an energy structure of a quantum well of the active layer 103 in FIG. 2. In FIG. 3, the quantum well of the invention comprises a quantum well layer 1 and GaAs barrier layers 2 and 6 stacked on both sides of the quantum well layer 1. In the GaAs barrier layers 2 and 6, GaPAs or GaNAs may also be used instead of GaAs. The quantum well layer 1 is constituted by successively stacking the GaInNAs layer 3 and the GaInAs layer 4. In the GaInNAs layer 3, GaInNAsSb may also be used instead of GaInNAs. Further, in the GaInAs layer 4, GaInAsSb may also be used instead of GaInAs. It is assumed that the layer thickness of the GaInNAs layer 3 is L1 and the thickness of the GaInAs layer 4 is L2 and that the layer thickness of the quantum well layer 1 as Lw, and the total of L1 and L2 is equal to Lw. The reason why the wavelength lengthening and reduction of the threshold current can be made compatible in the invention is to be described. In the invention, the GaInAs layer is added and stacked to the GaInNAs quantum well layer for attaining the wavelength lengthening to increase the net layer thickness of the quantum well. GaInAs is a material formed by removing N from GaInNAs. Accordingly, stacking of the GaInAs layer means increase in the thickness of the GaInNAs layer and removal of N from a layer with a predetermined thickness or more. Since lowering of the critical thickness durability is mainly attributable to the N addition, the critical thickness durability is improved for the layer removed with N.

Accordingly, a multi-layered quantum well layer having a quantum well layer with a larger net thickness than the critical thickness of GaInNAs and having its thickness less than the critical thickness can be prepared by defining the predetermined thickness to the critical thickness of the GaInNAs layer or less and stacking the GaInAs layer to the GaInNAs layer. Accordingly, it is possible to suppress the threshold current and lengthen the wavelength to such a range that can not be attained only with GaInNAs since the net quantum well layer thickness is more than critical thickness of GaInNAs. Accordingly, the wavelength lengthening and reduction of the threshold current as the object of the invention can be attained. Further, degradation of high speed property due to decrease of the carrier density does not occur by controlling the layer thickness of the GaInNAs layer 3 and the GaInAs layer 4 such that the first quantum level of the conduction band is present above the conduction band edge of the GaInAs layer 4 in FIG. 3.

In the device structure of FIG. 2, the quantum level energy of the quantum well layer was determined by the quantum mechanical calculation using the effective mass approximation and wavelength lengthening was studied.

As an example in FIG. 3, the GaInNAs layer 3 is formed of Ga_{0.65}In_{0.33N}_{0.01}As_{0.99} and the GaInAs layer 4 is formed of Ga_{0.65}In_{0.35}As. Further, since the critical thickness of GaInNAs-TQW is experimentally about 5 nm or less, the film thickness L1 for the GaInNAs layer 3 was set to 5 nm. At first, the condition where the first quantum level of the conduction band is present above the conduction band edge of the GaInAs layer 4 was: 0 nm≦L2≦2 nm.

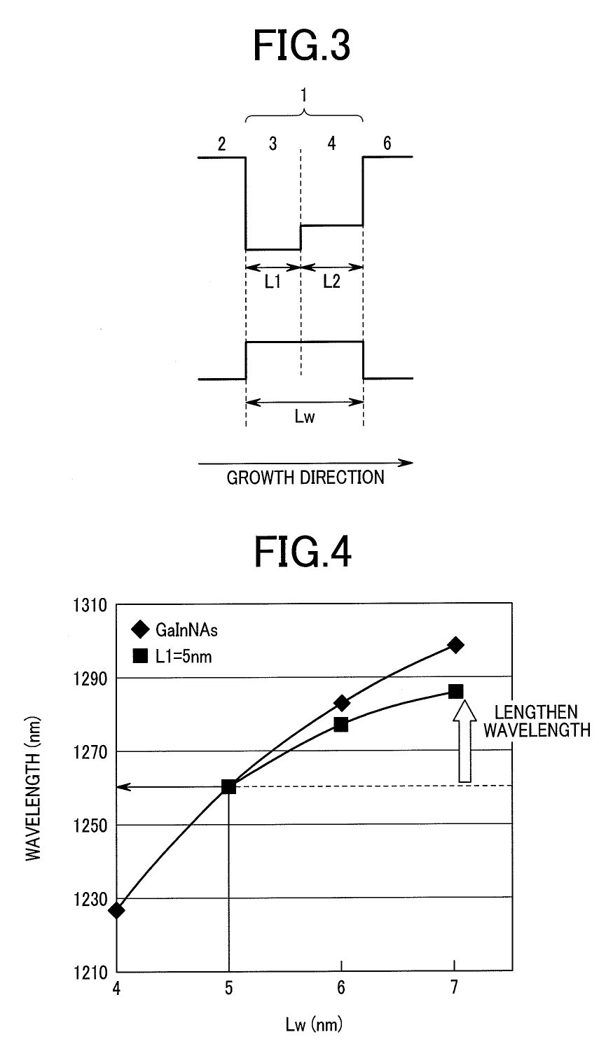

FIG. 4 shows a relation between the layer thickness Lw and the emission wavelength in the quantum well layer 1. In the graph, a relation between the layer thickness and the emission wavelength of a quantum well consisting only of the GaInNAs layer is also shown as a reference. In a curve at L1=5 nm in FIG. 4, a region (5 nm≦Lw≦7 nm) shows a wavelength when the thickness of the GaInAs layer 4 is increased. It can be seen from the result that the emission wavelength can be lengthened by 30 nm than the longest wavelength that can be attained only with the GaInNAs layer (at Lw=5 nm) by increasing the thickness of the GaInAs layer 4. Further, since the critical thickness of GaInAs is experimentally 7 nm or more, the quantum well of the invention is less than the critical thickness in the region (5 nm≦Lw≦7 nm). A threshold current can be about 7 mA at a room temperature and about 15 mA at 85° C., and operation at 30 Gbit/s was attained. From the foregoings, wavelength lengthening at a low threshold current as an object of the invention could be attained.

Then, the range for the layer thickness L1 of the GaInNAs layer 3 and the layer thickness L2 for the GaInAs layer 4 which are appropriate to make the wavelength lengthening and the reduction of the threshold value compatible in the case where the layer thickness L1 for the GaInNAs layer is 5 nm or less was studied.

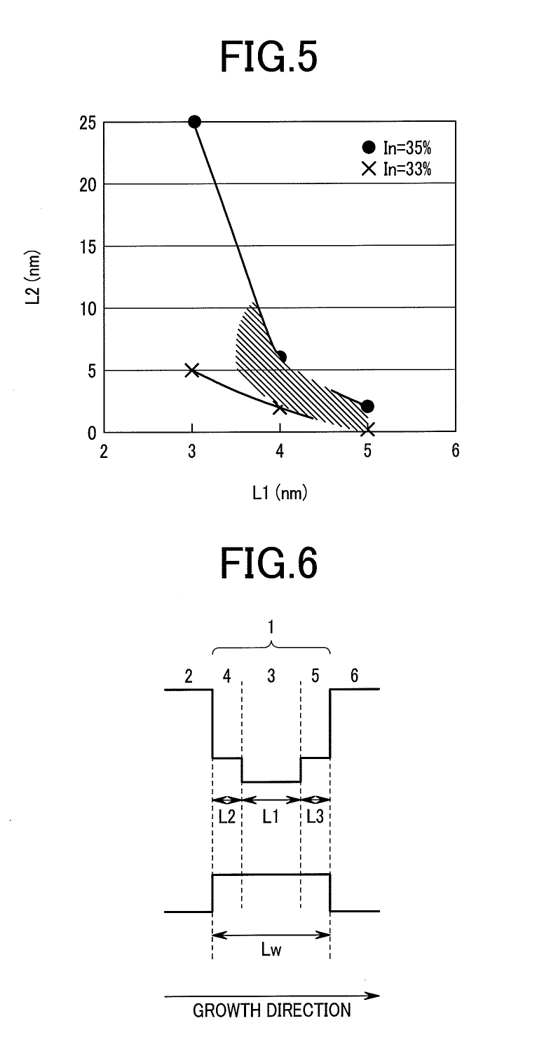

FIG. 5 shows a relation between the layer thickness L1 of the GaInNAs layer 3 and the layer thickness L2 of the GaInAs layer 4 where the position for the first quantum level of the conduction band is equal to the position for the conduction band edge of the GaInAs layer 4 of FIG. 3. In FIG. 5, a result in which the In composition of GaInAs is 33% is also plotted together. In FIG. 5, in the case where the layer thickness L2 is below the curves in each of the layer thickness L1, the first quantum level of the conduction band is present above the conduction band edge of the GaInAs layer. Further, in the quantum well of the invention, the position for the quantum level of the conduction band when the emission wavelength is made longest is equal to the position for the conduction band edge of the GaInAs layer 4.

Accordingly, the layer thickness L2 when the longest wavelength lengthening is attained in each of the layer thicknesses L1 is on the curve in FIG. 5. In the case where the In composition in GaInNAs is about 33%, the In composition in GaInAs is preferably 33% or more with a view point of the wavelength lengthening and this is preferably about 35% or less with a view point of strain. The range for the In composition satisfying such conditions in FIG. 5 is a region put between the two curves in FIG. 5. Then, the layer thickness L1 of the GaInNAs layer 3 is preferably from 3 to 5 nm with a view point of the critical thickness. Further, since the critical thickness of the GaInAs-TQW is experimentally about 7 nm or more, it is preferred that the layer thickness L2 of the GaInAs layer is about: L2≦10 nm. From the foregoings, it is preferred that the In composition and the layer thickness L1 for the GaInNAs layer 3 and the layer thickness L2 for the GaInAs layer 4 which are appropriate for attaining the wavelength lengthening and the reduction of the threshold current as the object of the invention are preferably about in a region shown by hatched lines in FIG. 5.

### Second Embodiment

A second embodiment is an example of applying the invention to a narrow stripe edge emitting laser. FIG. 2 shows a device structure of a narrow stripe edge emitting laser. The second embodiment has a feature in that the active layer 103 shown in FIG. 2 has a triple quantum well structure formed by stacking the active layer shown in FIG. 6 by three layers.

FIG. 6 is a view showing an energy structure of the quantum well of the active layer 103 in FIG. 2. In FIG. 6, the quantum well of the invention comprises a quantum well layer 1 and GaAs barrier layers 2 and 6 stacked on both sides of the quantum well layer 1. The quantum well layer 1 is formed by successively stacking the GaInAs layer 4, the GaInNAs layer 3, and the GaInAs layer 5. It is assumed that the thickness of the GaInNAs layer 3 is L1, the thickness of the GaInAs layer 4 is L2, and the thickness of the GaInAs layer 5 is L3. Further, it is assumed that the thickness of the quantum well layer 1 is Lw and the sum for L1, L2, and L3 is equal to Lw.

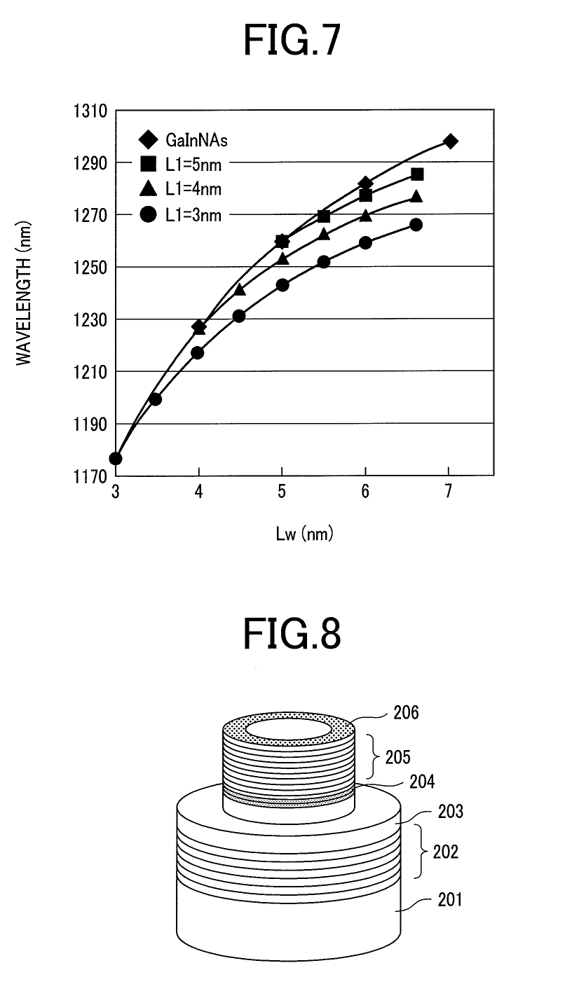

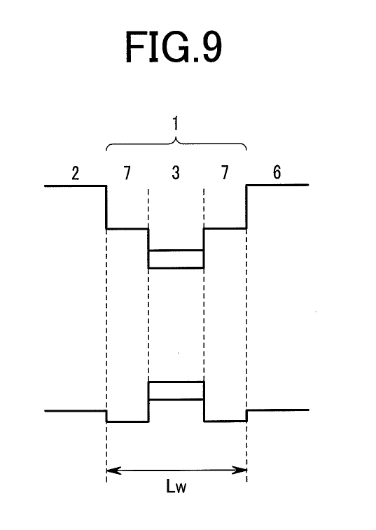

FIG. 7 shows a relation between the emission wavelength and the well layer thickness Lw in the case of forming the GaInAs layers 4 and 5 of Ga_{0.65}In_{0.35}As and forming the GaInNAs layer 3 of Ga_{0.65}In_{0.35}N_{0.01}As_{0.99}, and equally changing the thickness L2 of the GaInAs layer 4 and the thickness L3 of the GaInAs layer 5 with keeping L2=L3. Further, the first quantum level of the conduction band is present above the conduction band edges of the GaInAs layers 4 and 5 within a range for Lw calculated in FIG. 7 with respect to each layer thickness L1. In each of the curves for L1=5 nm, L1=4 nm, and L1=3 nm in FIG. 7, regions for: 5 nm≦Lw≦7 nm, 4 nm≦Lw≦7 nm, and 3 nm≦Lw≦7 nm show, respectively, the wavelength when the thickness of the GaInAs layers 4 and 5 are increased. Since the critical thickness of the GaInNAs-TQW determined experimentally is about 5 nm or less, wavelength could be lengthened by about 80 to 50 nm compared with the longest wavelength (1265 nm in view of FIG. 4) that can be achieved only with GaInNAs the invention when the GaInNAs layer 3 is about a critical thickness by applying the invention. Further, since the layer thicknesses of the GaInAs layer 4 and the GaInAs layer 5 are: 0 nm≦L2(3)≦1 nm, 0 nm≦L2(3)≦1.5 nm, and 0 nm≦L2(3)≦2 nm at L1=5 nm, L1=4 nm, and L1=3 nm respectively, the quantum well of the invention is less than the critical thickness. The threshold current could be attained as about 7 mA at a room temperature and as about 15 mA at 85° C. From the foregoings, wavelength could be lengthened at a low threshold current as the object of the invention.

### Third Embodiment

A third embodiment is an example of applying the invention to a surface emitting laser. FIG. 8 is a structural view of a surface emitting laser. There are shown an n-GaAs substrate 201 having a thickness of 1.5 μm, an n-GaAs-AlGaAs DBR reflection mirror 202 having a thickness of 4 μm, an active layer 203, an AlAs oxide current blocking layer 204, a p-GaAs/AlGaAs DBR reflection mirror 205 having a thickness of 3.5 μm, and a p-electrode 206. The active layer 203 has triple quantum well structure formed by stacking the active layer shown in FIG. 3 or FIG. 6 by three layers. Also in the surface light emitting laser, since reduction in the critical thickness durability can be moderated by N addition in GaInNAs by applying the invention, the wavelength lengthening by about 30 m could be attained as shown in FIG. 4 compared with conventional techniques. Further, the threshold current is about 2 mA at a room temperature, about 2.5 mA at 85° C., and operation at 10 Gbit/s was attained. As described above, wavelength could be lengthened at a low threshold current according to the invention.

Reference numerals used in the drawings of the application is described below.
1 quantum well layer
2 GaAs layer
3 GaInNAs layer
4 GaInAs layer
5 GaInAs layer
6 GaAs layer
101 n-GaAs substrate
102 n-GaInP cladding layer
103 active layer
104 p-GaInP cladding layer
105 SiO₂ protective film
106 polyimide insulative layer
107 p-electrode
201 n-GaAs substrate
202 n-GaAs/AlGaAs reflection mirror
203 active layer
204 oxide blocking layer
205 p-GaAs/AlGaAs reflection mirror
206 p-electrode

What is claimed is:

1. A semiconductor light emitting device comprising an active layer that generates light and is formed above a semiconductor substrate,
wherein the active layer includes a quantum well layer and semiconductor barrier layers, the quantum well layer being formed by stacking a first semiconductor layer and a second semiconductor layer that is adjacently formed on one side or both sides of the first semiconductor and that has a band gap energy larger than that of the first semiconductor layer, the semiconductor barrier layers being stacked on both sides of the quantum well layer and having a band gap energy larger than that of the second semiconductor layer in the quantum well layer; and
wherein the quantum level of the quantum well layer is present on the higher energy side than the band edge of the second semiconductor layer.

2. The semiconductor light emitting device according to claim 1, wherein the first semiconductor layer comprises GaInNAs and the second semiconductor layer comprises GaInAs.

3. The semiconductor light emitting device according to claim 2, wherein the semiconductor barrier layer comprises a material selected from one of GaAs, GaPAs, GaNAs, and GaNPAs.

4. The semiconductor light emitting device according to claim 2, wherein the GaInAs layer contains Sb.

5. The semiconductor light emitting device according to claim 4, wherein the semiconductor barrier layer comprises a material selected from one of GaAs, GaPAs, GaNAs, and GaNPAs.

6. The semiconductor light emitting device according to claim 2, wherein the GaInNAs layer contains Sb.

7. The semiconductor light emitting device according to claim 6, wherein the semiconductor barrier layer comprises a material selected from one of GaAs, GaPAs, GaNAs, and GaNPAs.

8. A semiconductor light emitting device comprising an active layer that generates light and is formed above a semiconductor substrate,
wherein the active layer includes a quantum well layer and semiconductor barrier layers, the quantum well layer being formed by stacking a GaInNAs layer and a GaInAs layer that is adjacently formed on one side or both sides of the GaInNAs layer, the semiconductor barrier layers being stacked on both sides of the quantum well layer and having a band gap energy larger than that of the GaInAs layer in the quantum well layer; and
wherein an In composition of the GaInNAs layer is 33% or more and 35% or less, an In composition of the GaInAs layer is 33% or more and 35% or less, and the thickness of the GaInNAs layer is 3 nm or more and 5 nm or less, and the thickness of the GaInAs layer is 2 nm or more and 7 nm or less.

9. The semiconductor light emitting device according to claim 8, wherein the semiconductor barrier layer comprises a material selected from one of GaAs, GaPAs, GaNAs, and GaNPAs.

10. The semiconductor light emitting device according to claim 8, wherein the GaInAs layer contains Sb.

11. The semiconductor light emitting device according to claim 10, wherein the semiconductor barrier layer comprises a material selected from one of GaAs, GaPAs, GaNAs, and GaNPAs.

12. The semiconductor light emitting device according to claim 8, wherein the GaInNAs layer contains Sb.

13. The semiconductor light emitting device according to claim 12, wherein the semiconductor barrier layer comprises a material selected from one of GaAs, GaPAs, GaNAs, and GaNPAs.

14. A semiconductor light emitting device comprising an active layer that generates light and is formed above a semiconductor substrate,
wherein the active layer includes a quantum well layer and semiconductor barrier layers, the quantum well layer being formed by stacking a GaInNAs layer and a GaInAs layer that is formed on one side or both sides of the GaInNAs layer, semiconductor barrier layers being stacked on both sides of the quantum well layer and having a band gap energy larger than that of quantum well layer; and
wherein the quantum level of the quantum well layer is present on the higher energy side than the band edge of the GaInAs layer, and an emission wavelength is 1260 nm or more and 1350 nm or less.

15. The semiconductor light emitting device according to claim 14, wherein the semiconductor barrier layer comprises a material selected from one of GaAs, GaPAs, GaNAs, and GaNPAs.

16. The semiconductor light emitting device according to claim 14, wherein the GaInAs layer contains Sb.

17. The semiconductor light emitting device according to claim 16, wherein the semiconductor barrier layer comprises a material selected from one of GaAs, GaPAs, GaNAs, and GaNPAs.

18. The semiconductor light emitting device according to claim 14, wherein the GaInNAs layer contains Sb.

19. The semiconductor light emitting device according to claim 18, wherein the semiconductor barrier layer comprises a material selected from one of GaAs, GaPAs, GaNAs, and GaNPAs.

20. A surface emitting or edge emitting laser having a semiconductor light emitting device according to claim 1.
